(19) United States
(12) Patent Application Publication
(10) Pub. No.: US 2015/0194620 A1
(43) Pub. Date: Jul. 9, 2015

(54) Surface Treatment for a Layer Made From a Fluorinated Material to Make it Hydrophilic

(71) Applicant: Commissariat a l'Energie Atomique et aux Energies Alternatives, Paris (FR)

(72) Inventors: Mohammed Benwadih, Champigny/Marne (FR); Olivier Poncelet, Grenoble (FR)

(73) Assignee: Commissariat a l'Energie Atomique et aux Energies Alternatives, Paris (FR)

(21) Appl. No.: 14/421,665

(22) PCT Filed: Aug. 12, 2013
(86) PCT No.: PCT/IB2013/056584

§ 371 Date: Feb. 13, 2015

(30) Foreign Application Priority Data
Aug. 13, 2012 (FR) 1257781

(51) Int. Cl. H01L 51/10; H01L 51/00; H01L 51/05

(52) U.S. Cl. CPC H01L 51/107; H01L 51/0508; H01L 51/0001

(57) ABSTRACT

The invention concerns a treatment method to make a surface of a layer made from a fluorinated material hydrophilic, a method for depositing a layer made from a metal or semi-conductive layer on the surface of a layer made from a fluorinated material, and a device comprising a layer made from a fluorinated material of which one surface has been treated by the treatment method of the invention, and a layer made from a metal material. The method of the invention comprises a step a) of depositing a layer of an oxo-hydroxide of an element from the alkaline earth metal group or from group II or III of the periodic table or of a rare earth or of a mixture of same, onto said surface. The method of the invention is applicable in the field of electronics, in particular.

The invention relates to a treatment process for rendering hydrophilic a surface of a layer made of a fluorinated material, to a process for depositing a layer made of a metallic or semiconductor material on the surface of a layer made of a fluorinated material, and also to a device comprising a layer made of a fluorinated material, one surface of which has been treated by the treatment process of the invention, and a layer made of a metallic material.

Many devices comprise layers made of a fluorinated material such as a fluorinated polymer (also referred to here as fluoropolymer) or made of a material containing at least one fluorine atom.

For example, fluoropolymers are used in the manufacture of electronic components such as organic transistors, for electrical insulation, or in the manufacture of mechanical parts subjected to extreme operating conditions, in terms of temperature or solvent aggressiveness.

In the particular case of organic electronics, fluoropolymers, and in particular Cytop®, which is a fluorinated polymer, have properties that are particularly suitable for forming the dielectric material of the gate of a transistor or of a capacitor or else the encapsulation layers used in this field.

However, the use of such fluorinated materials, in particular of such fluorinated polymers, which are hydrophobic, poses a problem, which to the knowledge of the inventors has not been solved to date: when it is desired to deposit other layers made of other materials on the layer of fluorinated material previously deposited as a thin layer, it is impossible to deposit these layers via a wet route, whether this is via the spin coating method or via various printing methods.

It is also impossible to adhesively bond together two parts made of fluoropolymers, or to adhesively bond a plastic material to a fluoropolymer.

This therefore makes it very tricky to manufacture complex devices comprising various elements essential for the operation thereof. This is for example the case for a complete transistor, in which the installation of the dielectric material (the fluorinated material) requires subsequent manufacturing steps.

Patent FR 2 919 521 proposes a device comprising a layer made of a fluorinated polymer, a portion at least of the surface of which is covered with a polymer comprising at least one fluorinated function and at least one acid or base function and that forms a tie layer on said fluorinated polymer, said tie layer being covered by another layer.

However, the tie layer is made of an ionically conductive material which disrupts the correct operation of the transistor.

The invention aims to provide a process that enables the naturally hydrophobic layer of a fluorinated material to be made hydrophilic, in order to allow the deposition of other layers on this layer made of fluorinated material.

For this purpose, the invention proposes a treatment process for rendering hydrophilic a surface of a layer made of a fluorinated material, characterized in that it comprises a step a) of depositing a layer of an (oxo)hydroxide of an element from the group of alkaline earth metals or from group II or from group III of the Periodic Table of the Elements or of a rare earth element or of a mixture thereof, on said surface.

Preferably, in step a), an (oxo)hydroxide of an element chosen from beryllium, magnesium, calcium, strontium, indium, barium, radium, aluminum, zinc, scandium, yttrium and mixtures thereof is deposited.

More preferably, in step a), said element is magnesium or aluminum and a magnesium hydroxide Mg(OH)₂ or an aluminum hydroxide Al(OH)₃ is deposited.

Still preferably, the thickness of the (oxo)hydroxide layer is between 10 nm and 1 μm. More preferably, this thickness is between 10 and 300 nm inclusive. More preferably still, it is equal to 50 nm.

According to a first embodiment of the treatment process of the invention, step a) of deposition on said surface is a step of hydrolysis, on said surface, of a salt of said element.

When the element is magnesium, preferably said salt is MgCl₂ and the hydrolysis is carried out at pH 9.

According to a second embodiment of the treatment process of the invention, step a) is a step of depositing said (oxo)hydroxide of said element in suspension in a solvent.

In this second embodiment, preferably, said suspension is a colloidal sol of said (oxo)hydroxide of said element.

Preferably, the layer made of a fluorinated material is a layer made of a fluorinated polymer or of fluorinated silane.

The invention also proposes a process for depositing a layer made of a material selected from a metallic material, an electrically conductive material, a semiconductor material and an insulating material on the surface of a layer made of a fluorinated material, characterized in that it comprises a step of treating said surface of the layer made of a fluorinated material in order to make it hydrophilic via the process according to the invention, followed by a step of depositing said layer made of a metallic or electrically conductive or semiconductor or insulating material.

Preferably, in this process, the material is a metallic material selected from silver, chromium, gold, titanium, aluminum, platinum, palladium, copper, nickel, molybdenum or a conductive ink, in particular comprising metallic nanoparticles.

When the material is a metallic electrically conductive material, it is preferably selected from a conductive polymer, such as PEDOT/PSS: poly(3,4-ethylenedioxythiophene) (PEDOT)/sodium poly(styrene sulfonate) (PSS), polyaniline, conductive metal oxides selected from ITO (indium tin oxide), AZO (aluminum zinc oxide conductive alloy), WO₃ (tungsten oxide), carbon nanotubes, graphene, silver/graphene mixtures, or else copper/graphene mixtures.

The invention also proposes a device, characterized in that it comprises a layer made of a fluorinated material, a surface of which is coated with a layer made of an (oxo)hydroxide of an element selected from the group of alkaline earth metals or from group II or group III of the Periodic Table of the Elements or of a rare earth element and a layer made of a material selected from a metallic material, an electrically conductive material, a semiconductor material and an insulating material deposited on the surface of the (oxy)hydroxide layer not in contact with the layer made of a fluorinated material.

Preferably, in the device of the invention, the (oxo)hydroxide is an (oxo)hydroxide of an element selected from beryllium, magnesium, calcium, strontium, indium, barium, radium, aluminum, zinc, scandium, yttrium and mixtures thereof.

More preferably, the (oxo)hydroxide is a magnesium hydroxide Mg(OH)₂ or an aluminum hydroxide Al(OH)₃.

Preferably, in the device of the invention, the thickness of the (oxo)hydroxide layer is between 10 and 300 nm inclusive. Preferably, it is equal to 50 nm.

Still preferably, the layer made of a fluorinated material is a layer made of a fluorinated polymer or made of a fluorinated silane.

As regards the layer made of a metallic material, it is preferably made of a material selected from silver, chromium, gold, titanium, aluminum, platinum, palladium, copper, nickel, molybdenum or a conductive ink, in particular comprising metallic nanoparticles.

As regards the layer made of an electrically conductive material, it is preferably made of a material selected from a conductive polymer, such as PEDOT/PSS: poly(3,4-ethylenedioxythiophene) (PEDOT)/sodium poly(styrene sulfonate) (PSS), polyaniline, conductive metal oxides selected from ITO (indium tin oxide), AZO (aluminum zinc oxide alloy), WO₃ (tungsten oxide), carbon nanotubes, graphene, silver/graphene mixtures or else copper/graphene mixtures.

A preferred device according to the invention is an organic transistor.

The invention will be better understood, and other features and advantages thereof will appear more clearly, on reading the explanatory description which follows and which is given with reference to the appended figures, in which:

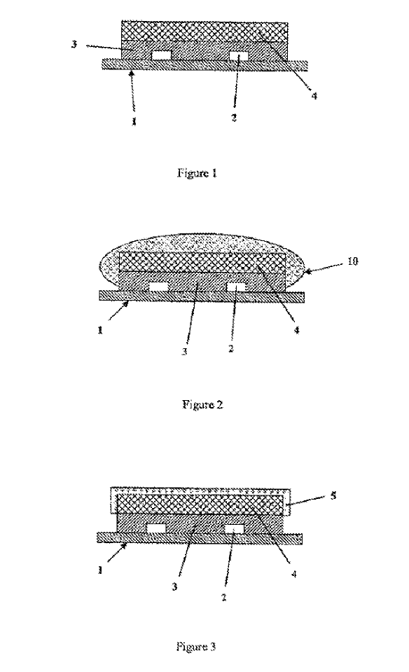

FIG. 1 schematically represents the structure of an organic transistor before the deposition of the gate,

FIG. 2 represents the transistor from FIG. 1 undergoing treatment by the process of the invention before the deposition of the gate,

FIG. 3 schematically represents the transistor obtained after the treatment carried out as shown in FIG. 2,

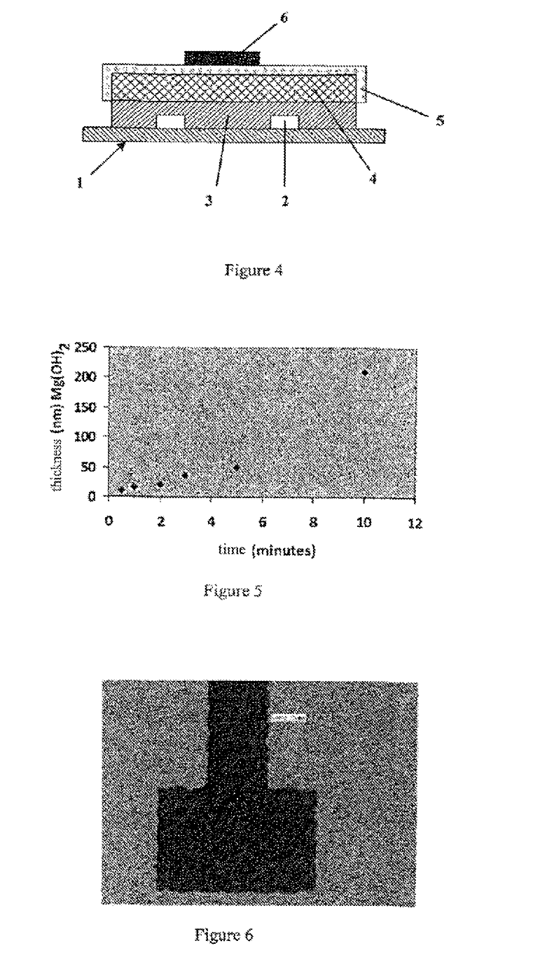

FIG. 4 represents the transistor from FIG. 3 with the gate deposited,

FIG. 5 represents the increase in the thickness of the layer obtained during the treatment of the surface of a fluorinated polymer by the process of the invention, as a function of time,

FIG. 6 shows a photograph taken using an optical microscope at ×5 magnification of the surface of a layer made of a fluorinated polymer, Cytop®, from the prior art on which an electrode has been printed with a silver ink,

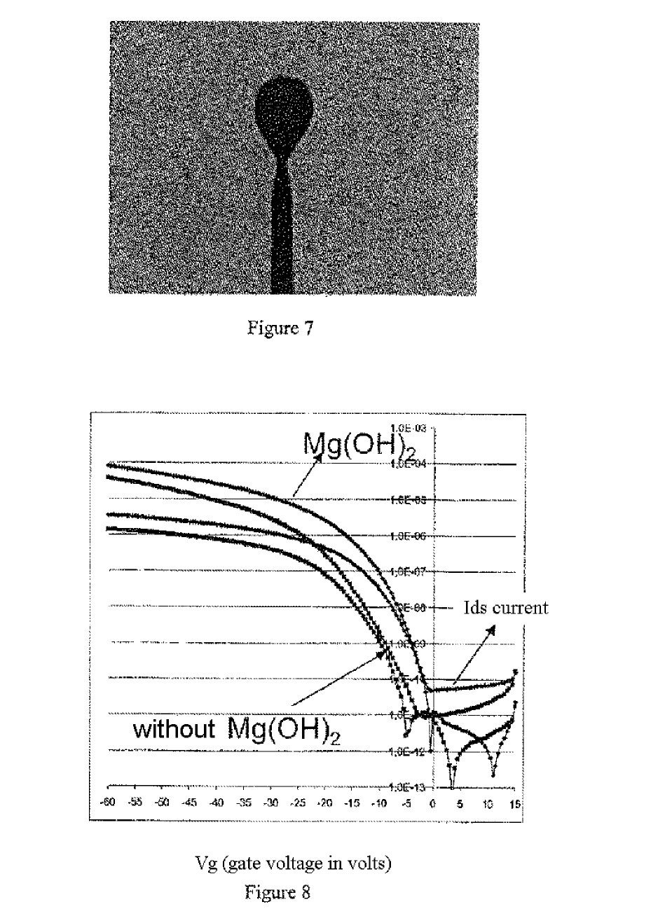

FIG. 7 shows a photograph taken using an optical microscope at ×5 magnification of the surface of a layer made of a fluorinated polymer, Cytop®, treated according to the invention, on which an electrode has been printed with a silver ink, and

FIG. 8 represents the variation in the gate voltage, Vg, in volts, of a transistor of the prior art and of a transistor according to the invention.

In order to allow the deposition of layers, in particular made of a metallic material or made of an electrically conductive material or made of a semiconductor material or an insulating material, on the surface of a layer made of a fluorinated material, the invention proposes covering the surface of the layer made of a fluorinated material with the aid of an additional layer referred to as a “tie” layer which makes it possible to obtain a hydrophilic surface on which a layer may be deposited, in particular a layer made of a metal such as silver, chromium, gold, titanium, aluminum, platinum, palladium, copper, nickel, molybdenum or a conductive ink, in particular comprising metallic nanoparticles.

As regards the electrically conductive material, it is preferably selected from a conductive polymer such as PEDOT/PSS: poly(3,4-ethylenedioxythiophene) (PEDOT)/sodium poly(styrene sulfonate) (PSS), polyaniline, conductive metal oxides selected from ITO (indium tin oxide), AZO (aluminum zinc oxide alloy), WO₃ (tungsten oxide), carbon nanotubes, graphene, silver/graphene mixtures or else copper/graphene mixtures.

An adherent structure is then obtained.

The invention proposes to modify the wettability of the surface of the layer made of a fluorinated material by creating a tie layer formed of a hydroxide or of an oxohydroxide of an alkaline earth metal or of an element from group II or from group III of the Periodic Table of the Elements or of a rare earth element.

Depending on the element, either a pure hydroxide or an oxohydroxide, that is to say a hydrated oxide, will be formed.

Thus, in the text which follows, this layer will generally be referred to as an “(oxo)hydroxide layer” to designate both a layer made of a hydroxide of the element and a layer made of an oxohydroxide of the element.

This element may be beryllium, magnesium, calcium, strontium, indium, barium, radium, aluminum, zinc, scandium, yttrium and mixtures thereof.

It will be very particularly preferred to use, as the element, magnesium or aluminum, in which case the layer formed will be a layer of brucite, Mg(OH)₂, or of gibbsite, Al(OH)₂, respectively.

Specifically, layers of brucite or gibbsite have the advantage of being electrically insulating and possess a relatively high permittivity of the order of 8 and above.

But above all, brucite and gibbsite grow on layers made of fluorinated polymers and exhibit aptitudes for adhering to fluorinated polymers such as Teflon® or Cytop®, and to a layer made of a fluorosilane, and also to other materials, for example fluorinated adhesives.

Furthermore, when use is made of a conductive ink, that is to say an ink containing a metal, this ink adheres to the brucite or to the gibbsite, which makes it possible to deposit, in particular in the case of transistors where the layer made of dielectric material is often made of a fluorinated polymer, another layer made of a metal, for example in order to form the gate electrode, by techniques such as printing, spin coating or adhesive bonding.

Thus, the invention finds an application more particularly in the field of organic transistors.

Specifically, it is now acknowledged that in order to obtain organic transistors that exhibit little hysteresis and high mobilities, it is necessary for the dielectric material of the gate to be made of a polymer having a low c value (referred to as a low K polymer) (J. Veres et al., “Gate Insulators in Organic Field-Effect Transistors”, Chem. Mater., 2004, 16, 4543-4555).

Among the low K polymers, fluoropolymers are materials of choice. It is therefore necessary to deposit the other layers that form the stack of a transistor on this layer.

FIG. 1 schematically represents the structure of an organic transistor before the deposition of the gate.

As is seen in FIG. 1, such a transistor consists of a substrate, denoted by 1 in FIG. 1, generally made of polyethylene naphthalate (PEN) generally having a thickness of 125 μm.

As examples of materials capable of forming such a substrate, mention may especially be made of silica, silicon, polyethylene terephthalate (PET), polyethylene naphthalate (PEN), polyimide (PI), polyetherimide (PEI), polyethersulfone (PES), polysulfone (PSF), polyphenylene sulfide (PPS), polyetheretherketone (PEEK), polyacrylate (PA), polyamide-imide (PAI), polystyrene, polyethylene, polypropylene, a polyamine resin, a carbonate resin or else a cellulose resin.

Deposited on this substrate are two electrodes, denoted by 2 in FIG. 1, referred to as source electrode and drain electrode.

These electrodes are structured, that is to say that their surface is not flat. These electrodes are structured by a laser treatment or by photolithography.

These electrodes are generally made of gold, have a thickness of 30 nm and are deposited by evaporation.

As shown in FIG. 1, these electrodes 2 and a portion of the substrate 1 are covered with a layer, denoted by in FIG. 1, made of a semiconductor material, generally of the TIPS pentacene type, which is a small semiconductor molecule deposited by a printing technique such as photogravure, or made of tetracene or made of anthracene. As other examples of such materials, mention may be made of two types of organic semiconductor materials considered within the context of the present invention. These may be molecules of low molecular mass (commonly referred to as “small molecules”), and in particular molecules having a molecular mass of less than 1000 g/mol, or polymers consisting of macromolecules of greater molecular mass. These two types of organic semiconductors share a trait of having a conjugated system originating from the alternation of single and double carbon-carbon bonds. As an organic semiconductor of low molecular mass, mention may for example be made of those of polyacene, oligothiophene or phthalocyanine type. As a polymer organic semiconductor, mention may for example be made of those of polyacetylene, polyphenylene, polythiophene or poly(phenylene vinylene) type. It can in particular be an organic semiconductor selected from pentacene, tetracene, anthracene, naphthalene, alpha-6-thiophene, alpha-4-thiophene, perylene and derivatives thereof, rubrene and derivatives thereof, coronene and derivatives thereof, perylenetetracarboxylic diimide and derivatives thereof, perylenetetracarboxylic dianhydride and derivatives thereof, polythiophene and derivatives thereof, poly(para-phenylene vinylene) and derivatives thereof, poly(para-phenylene) and derivatives thereof, polyfluorene and derivatives thereof, a copolymer of polyfluorene-oligothiophene and derivatives thereof, polythiophene vinylene) and derivatives thereof, a heterocyclic aromatic copolymer of polythiophene and derivatives thereof, an oligonaphthalene and derivatives thereof, alpha-5-thiophene oligothiophene and derivatives thereof, phthalocyanine which contains no metal and derivatives thereof, pyromellitic dianhydride and derivatives thereof, pyromellitic diimide and derivatives thereof, perylenetetracarboxylic acid dianhydride and derivatives thereof, perylenetetracarboxylic diimide and derivatives thereof, naphthalenetetracarboxylic diimide and derivatives thereof, or naphthalenetetracarboxylic acid dianhydride and derivatives thereof.

The gate electrode must then be deposited. For this, a layer, denoted by 4 in FIG. 1, made of a fluorinated polymer is deposited on the layer 3.

The fluorinated polymer used is generally a Cytop® fluoropolymer having a thickness of between 500 and 800 nm inclusive.

It is then necessary to deposit the gate electrode, denoted by 6 in FIG. 4, on this layer 4 made of fluorinated polymer. This gate electrode has a thickness of between 50 nm and 1 μm inclusive.

Due to the stated difficulties of depositing on the layer 4 made of fluorinated polymer, there is a lack of adhesion between the layer 4 and the upper layer 6, namely the gate electrode. These layers are therefore not uniform.

Owing to the process of the invention for the treatment of a surface to make the surface of a layer made of a fluorinated material hydrophilic, it is possible to deposit conductive inks by screen printing or by ink jet printing or by photogravure or by flexo printing or by any other technique for depositing a liquid solution. It is then possible to print the gate of a transistor.

The treatment process of the invention for making the surface of the layer 4 made of a fluorinated material hydrophilic is represented schematically in FIG. 2.

As is seen in FIG. 2, where the layers identical to those shown in FIG. 1 bear the same numbers as in FIG. 1, a drop, denoted by 10 in FIG. 2, of a liquid solution of a element from the group of alkaline earth metals or from group III of the Periodic Table of the Elements or of a rare earth element is deposited on the surface of the fluorinated layer 4.

This drop 10 covers the whole of the layer 4.

A layer, denoted by 5 in FIG. 3, of hydroxide or of oxohydroxide of the element is then obtained, after drying in order to evaporate the solvent from the solution deposited.

In particular, when the element is magnesium or aluminum, due to the affinity of brucite, Mg(OH)₂, and of gibbsite, Al(OH)₂, with the fluorinated surface of the layer 4, a sheet of brucite or of gibbsite is formed over the entire exposed surface of the layer 4.

The thickness of this layer 5 varies as a function of the contact time between the solution of the element from the group of alkaline earth metals or from group II or III of the Periodic Table or of the rare earth element on the surface of the layer 4.

It is then possible to deposit an electrically conductive ink in order to form the gate electrode on the layer 5 thus formed, as shown in FIG. 4, where the gate electrode is denoted by 6.

The layer 5, referred to as tie layer, has a thickness generally of between 10 nm and 1 μm inclusive. It is preferably of between 10 and 300 nm inclusive. However, in a transistor, it is preferably 50 nm.

The solution deposited on the layer 4 may be a solution of the element to be deposited itself, for example a colloidal sol of the hydroxide of the element or of the oxohydroxide of the element. In particular, in the case of brucite and gibbsite, use may be made, respectively, of a colloidal sol of magnesium hydroxide Mg(OH)₂ or of aluminum hydroxide Al(OH)₂.

However, use may also be made of an aqueous solution of a salt of this element and the hydrolysis of this salt, in order to obtain the desired (oxo)hydroxide of the element, may be carried out in situ, that is to say directly on the layer 4.

For example, use may be made of magnesium chloride MgCl₂ or magnesium fluoride MgF₂ or aluminum chloride that will be dissolved in water. This solution will be deposited on the layer 4 and a sodium hydroxide solution will then be poured onto the magnesium chloride solution. The reaction for forming the film of brucite on the layer 4 starts from pH 9.

Next, the thickness of the layer of brucite increases on the layer 4.

FIG. 5 shows the variation in thickness of a layer of brucite Mg(OH)₂ as a function of the soaking time of a Cytop® layer in a solution containing 100 mg of MgCl₂ in 200 ml of water, to which a solution of sodium hydroxide, NaOH, having a concentration of 0.5 mol/1 has been added until a pH of 9 is obtained.

As is seen in FIG. 5, a layer 5 of brucite having a thickness of 50 nm is obtained in 5 minutes.

In order to obtain a transistor, it is then necessary to deposit the gate electrode 6 on this tie layer 5.

Thus, the invention also proposes a process for depositing a layer 6 made of a metallic material or made of an electrically conductive material such as a conductive polymer such as PEDOT/PSS, (poly(3,4-ethylenedioxythiophene) (PEDOT) and sodium poly(styrene sulfonate) (PSS)) or made of a semiconductor material such as one of those mentioned previously or made of an insulating material on the surface of a layer 4 made of a fluorinated material, this process comprising a step of treating the surface of the layer 4, in order to create thereon the tie layer 5, as shown above, by the treatment process of the invention, and then the deposition of said layer 6 made of a metallic or semiconductor material.

The metallic material is preferably selected from silver, chromium, gold, titanium, aluminum, platinum, palladium, copper, nickel, molybdenum or a conductive ink, in particular comprising metallic nanoparticles.

As regards the electrically conductive material, it is preferably selected from a conductive polymer such as PEDOT/PSS: poly(3,4-ethylenedioxythiophene) (PEDOT)/sodium poly(styrene sulfonate) (PSS), polyaniline, conductive metal oxides selected from ITO (indium tin oxide), AZO (aluminum zinc oxide alloy), WO₃ (tungsten oxide), carbon nanotubes, graphene, silver/graphene mixtures or else copper/graphene mixtures.

The devices obtained by these processes are also a subject matter of the invention.

Thus, a device according to the invention comprises a layer 4 made of a fluorinated material, such as a fluorinated polymer or a fluorosilane, one surface of which is coated with a layer of a hydroxide or of an oxyhydroxide of a element from the group of alkaline earth metals or from group II or III of the Periodic Table of the Elements or of a rare earth element or mixtures thereof.

The device of the invention may furthermore comprise a layer 6 made of a metallic or electrically conductive or semiconductor or insulating material, deposited over all or part of the surface of the layer 5.

In order to make the invention better understood, one embodiment thereof will now be described by way of a purely illustrative and nonlimiting example.

### EXAMPLE 1

On a substrate 1 made of polyethylene naphthalate (PEN) having a thickness of 125 μm, a layer 2 made of gold, having a thickness of 30 nm, was deposited by evaporation or by phase vapor deposition (PVD).

This gold layer 2 is etched in order to form source and drain electrodes. This may be carried out by photolithography or by laser ablation.

A layer 3 of a TIPS pentacene semiconductor material having a thickness of 100 nm is then deposited by photogravure.

The layer 4 made of a dielectric material, which here is a fluorinated polymer, Cytop®, having a thickness of 800 nm, is then deposited.

This layer 4 was formed by screen printing.

The treatment of the surface of this layer 4 via the treatment process of the invention is then carried out.

For this purpose, use was made of a solution consisting of 100 mg of magnesium chloride, MgCl₂, which is dissolved in water at a concentration of 100 mg/ml.

A second solution of NaOH in water at a concentration of 100 mg/ml is manufactured.

The device obtained is immersed in the solution of MgCl₂.

The solution of NaOH is carefully added until a pH of 9 is obtained.

When the pH is less than 9, for example equal to 8, the reaction is very slow to start. When the pH is greater than 10, the reaction is very fast but the other layers could be damaged.

The hydrolysis reaction begins on the fluorine of the layer 4 due to the difference in electronegativity between fluorine, which is electronegative, and magnesium, which is electropositive.

A seed of brucite Mg(OH)₂ forms on the surface of the layer 4.

The device is kept in the solution.

In the end, a deposition in the form of sheets of brucite which cover the entire surface of the layer 4 is obtained. After 5 minutes, a transparent layer having a thickness of 50 nm is obtained.

Brucite crystallizes in the rhombohedral system.

Washing is then carried out with water and drying is carried out with an air gun or a slight annealing at 100° C. is carried out for 5 min.

The contact angle of a drop of water of the surface of the layer 5 thus formed is measured.

The contact angle of the drop of water is less than 5°.

The gate electrode 6 that also contains silver nanoparticles is then deposited by ink jet on the surface of this layer 5.

The device shown in FIG. 6 is then obtained. The electrode 6 has a thickness of 1 μm.

FIG. 6 is a top-view photograph of the device. As is seen, the gate formed does not dewet and has clearly defined contours.

### EXAMPLE 2 (COMPARATIVE)

The same device as in example 1 was manufactured but without treating the layer 4 with the treatment process of the invention.

The contact angle of a drop of water on the surface obtained was measured.

The contact angle was 110°.

The device obtained is shown in FIG. 7, where the layer 4 represents the device seen from above, the layer of fluorinated polymer being denoted by 4 and the layer of silver nanoparticles ink being denoted by 6.

As is seen from FIGS. 6 and 7 and from the water drop angle measurements, the treatment process of the invention for making the surface of a fluorinated material hydrophilic is entirely effective.

The devices obtained in examples 1 and 2 were then tested electrically by plotting the curves characteristic of a field-effect transistor.

The curves obtained are shown in FIG. 8.

As is seen in FIG. 8, with the layer for treatment according to the invention, the curve has a greater current.

1. A treatment process for rendering hydrophilic a surface of a layer comprising a fluorinated material, it wherein the process comprises a step a) of depositing a layer comprising an (oxo)hydroxide of an element selected from the group consisting of alkaline earth metals, Group II and Group III of the Periodic Table of the Elements, a rare earth element and a mixture thereof on the surface.

2. The process as claimed in claim 1, wherein, in step a), an (oxo)hydroxide of an element selected from the group consisting of beryllium, magnesium, calcium, strontium, indium, barium, radium, aluminum, zinc, scandium, yttrium and mixtures thereof is deposited.

3. The process as claimed in claim 1, wherein, in step a), the element is magnesium or aluminum and in that a magnesium hydroxide Mg(OH)₂ or an aluminum hydroxide Al(OH)₃ is deposited.

4. The process as claimed in claim 1, wherein the thickness of the layer of the (oxo)hydroxide is between 10 nm and 1 μm inclusive.

5. The process as claimed in claim 1, wherein step a) of deposition on the surface is a step of hydrolysis, on the surface, of a salt of the element.

6. The process as claimed in claim 5, wherein the salt of the element is MgCl₂ and in that the hydrolysis is carried out at pH 9.

7. The process as claimed in claim 1, wherein step a) is a step of depositing the (oxo)hydroxide of the element in suspension in a solvent.

8. The process as claimed in claim 7, wherein the suspension is a colloidal sol of the (oxo)hydroxide of the element.

9. The process as claimed in claim 1, wherein the fluorinated material is a fluorinated polymer or fluorinated silane.

10. A process for depositing a layer comprising a material selected from the group consisting of a metallic or electrically conductive or semiconductive or insulating material on the surface of the layer comprising a fluorinated material, wherein the process comprises a step of treating the surface of the layer comprising the fluorinated material to make it hydrophilic via the process according to claim 1, to form the layer comprising the (oxo)hydroxide, followed by a step of depositing the layer comprising a metallic or electrically conductive or semiconductor or insulating material on the layer comprising the (oxo)hydroxide.

11. The process as claimed in claim 10, wherein the material comprises a metallic material selected from the group consisting of silver, chromium, gold, titanium, aluminum, platinum, palladium, copper, nickel, molybdenum and a conductive ink.

12. The process as claimed in claim 10, wherein the material is an electrically conductive material selected from the group consisting of PEDOT/PSS (poly(3,4-ethylenedioxythiophene) (PEDOT)/sodium poly(styrene sulfonate) (PSS)), polyaniline, ITO (indium tin oxide), AZO (aluminum zinc oxide conductive alloy), WO₃, carbon nanotubes, graphene, silver/graphene mixtures and copper/graphene mixtures.

13. A device, comprising a layer comprising a fluorinated material, a surface of which is coated with a layer comprising an (oxo)hydroxide of an element selected from the group consisting of alkaline earth metals, Group II and Group III of the Periodic Table of the Elements, rare earth element and a layer comprising a material selected from the group consisting of a metallic or electrically conductive or semiconductive or insulating material deposited on the surface of the layer comprising an (oxo)hydroxide not in contact with the layer comprising a fluorinated material.

14. The device as claimed in claim 13, wherein the (oxo)hydroxide is an (oxo)hydroxide of an element selected from the group consisting of beryllium, magnesium, calcium, strontium, indium, barium, radium, aluminum, zinc, scandium, yttrium and mixtures thereof.

15. The device as claimed in claim 13, wherein the (oxo)hydroxide is magnesium hydroxide Mg(OH)₂ or aluminum hydroxide Al(OH)₃.

16. The device as claimed in claim 13, wherein the thickness of the layer comprising an (oxo)hydroxide is between 10 nm and 1 μm inclusive.

17. The device as claimed in claim 13, wherein the fluorinated material is a fluorinated polymer or a fluorinated silane.

18. The device as claimed in claim 13, wherein the metallic material is selected from the group consisting of silver, chromium, gold, titanium, aluminum, platinum, palladium, copper, nickel, molybdenum and a conductive ink comprising metallic nanoparticles.

19. The device as claimed in claim 13, wherein the electrically conductive material is selected from the group consisting of PEDOT/PSS (poly(3,4-ethylenedioxythiophene) (PEDOT)/sodium poly(styrene sulfonate) (PSS)), polyaniline, ITO (indium tin oxide), AZO (aluminum zinc oxide alloy), tungsten oxide, carbon nanotubes, graphene, silver/graphene mixtures and copper/graphene mixtures.

20. The device as claimed in claim 14, wherein the device is an organic transistor.
